(19) United States
(12) Patent Application Publication
(10) Pub. No.: US 2013/0284093 A1
(43) Pub. Date: Oct. 31, 2013

(54) SUBSTRATE TREATING APPARATUS

(71) Applicant: SEMES CO., LTD., Chungcheongnam-do (KR)

(72) Inventors: Yong Su JANG, Chungcheongnam-do (KR); Jung Il SONG, Chungcheongnam-do (KR); Sun Rae KIM, Gyeonggi-do (KR); Sung Hawn HONG, Chungcheongnam-do (KR); Tae Hyo LEE, Chungcheongnam-do (KR)

(73) Assignee: SEMES CO., LTD., Chungcheongnam-do (KR)

(21) Appl. No.: 13/873,481

(22) Filed: Apr. 30, 2013

(30) Foreign Application Priority Data
Apr. 30, 2012 (KR) 10-2012-0045742
Apr. 30, 2012 (KR) 10-2012-0045743
Aug. 7, 2012 (KR) 10-2012-0086440
Aug. 7, 2012 (KR) 10-2012-0086441

(51) Int. Cl. C23C 16/44

(52) U.S. Cl. CPC C23C 16/4415
USPC 118/723 ME

(57) ABSTRACT

Provided is a substrate treating apparatus. The substrate treating apparatus includes a process chamber providing an inner space in which a substrate is treated, a substrate support member disposed within the process chamber to support the substrate, a showerhead disposed to face the substrate support member and partitioning the inner space into an upper space and a lower space, the showerhead having a plasma supply hole through which the upper space and the lower space communicate with each other, an excitation gas supply unit supplying an excitation gas into the upper space, a process gas supply unit supplying a process gas into the lower space, and a microwave apply unit applying a microwave into the upper space.

### CROSS-REFERENCE TO RELATED APPLICATIONS

This U.S. non-provisional patent application claims priority under 35 U.S.C. §119 of Korean Patent Application Nos. 10-2012-0045742, filed on Apr. 30, 2012, 10-2012-0045743, filed on Apr. 30, 2012, 10-2012-0086440, filed on Aug. 7, 2012, and 2012, 10-2012-0086441, filed on Aug. 7, 2012, the entire contents of which are hereby incorporated by reference.

### BACKGROUND OF THE INVENTION

The present invention disclosed herein relates to a substrate treating apparatus, and more particularly, to an apparatus for treating a substrate by using plasma.

In manufacturing of semiconductor devices, it is required to form a monocrystalline silicon layer on a substrate. The silicon layer is formed on a top surface of the substrate on which a pattern is formed. Here, the process of forming the silicon layer may be performed after an oxide layer formed on the top surface of the substrate is removed. A method of a monocrystalline silicon layer on substrate includes a low pressure chemical vapor deposition (LPCVD) and ultra high vacuum chemical vapor deposition (UHVCVD).

The LPCVD is performed at a temperature of about 850° C. or more to grow the monocrystalline silicon layer on the substrate. When the silicon layer is grown at a high temperature, impurities contained in the substrate may be diffused. For example, the impurities may be contained in a source/drain junction area that is provided for forming a transistor. When the impurities are diffused, it may be difficult to form a shallow junction area.

The UHVCVD is performed at a temperature of about 700° C. to grow the monocrystalline silicon layer. However, the UHVCVD may have a low growth rate and substrate treating efficiency.

### SUMMARY OF THE INVENTION

The present invention provides a substrate treating apparatus that generates plasma by using microwaves.

The present invention also provides a substrate treating apparatus that forms a high-density silicon layer on a substrate.

The present invention also provides a substrate treating apparatus that forms a silicon layer on a substrate at a low temperature.

The present invention also provides a substrate treating apparatus that prevents impurities from being diffused.

The present invention also provides a substrate treating apparatus that adjusts distribution of a layer formed on a substrate.

Embodiments of the present invention provide substrate treating apparatuses including: a process chamber providing an inner space in which a substrate is treated; a substrate support member disposed within the process chamber to support the substrate; a showerhead disposed to face the substrate support member and partitioning the inner space into an upper space and a lower space, the showerhead having a plasma supply hole through which the upper space and the lower space communicate with each other; an excitation gas supply unit supplying an excitation gas into the upper space; a process gas supply unit supplying a process gas into the lower space; and a microwave apply unit applying a microwave into the upper space.

In some embodiments, the process gas supply unit may include: a first process gas supply part supplying the process gas into the lower space from the showerhead; and a second process gas supply part supplying the process gas into the lower space from an inner wall of the process chamber.

In other embodiments, the first process gas supply part may include: a distribution line through which the excitation gas flows, the distribution line being disposed within the showerhead; and spray holes defined in a bottom surface of the showerhead to communicate with the distribution line, the spry holes spraying the process gas into the lower space.

In still other embodiments, each of the spray holes may be inclined with respect to a straight line perpendicular to the bottom surface of the showerhead.

In even other embodiments, the spray holes may include: a first spray hole inclined with respect to a straight line perpendicular to the bottom surface of the showerhead; and a second spray hole inclined with respect to the straight line in a direction different from that of the first spray hole.

In yet other embodiments, the showerhead may include: a fixed part fixed to the process chamber; and rib parts extending inward from the fixed part, wherein the plasma supply hole may be defined between the rib parts or between the rib parts and the fixed part.

In further embodiments, the distribution line may be disposed inside the rib parts, and the spray holes may be defined in the rib parts, respectively.

In still further embodiments, the distribution line may be disposed inside the fixed part and the rib parts, and the spray holes may be defined in the rib parts, respectively.

In even further embodiments, the rib parts may include: a plurality of distribution rib parts having radii different from each other with respect to a center of the showerhead; and a connection rib part disposed between the distribution rib parts or between the distribution rib parts and the fixed part.

In yet further embodiments, the substrate treating apparatuses may further include: a process gas tank supplying the process gas; and a showerhead line connecting the process gas tank to the distribution line.

In much further embodiments, the distribution line may be provided in plurality in each of the distribution ribs, and the plurality of distribution lines respectively have separate passages, and the showerhead line may be branched and connected to each of the distribution lines having the separate passages.

In still much further embodiments, the distribution rib parts may include: a first distribution rib part, a second distribution rib part, and a third distribution rib part which are successively disposed in a radius direction of the showerhead, and the distribution line may include a first distribution line, a second distribution line, and a third distribution line which are respectively disposed in the first distribution rib part, the second distribution rib part, and the third distribution rib part.

In even much further embodiments, the first distribution line and the second distribution line may communicate with each other, and the third distribution line may have a passage different from those of the first and second distribution lines.

In yet much further embodiments, the first distribution line and the third distribution line may communicate with each other, and the second distribution line may have a passage different from those of the first and third distribution lines.

In still yet much further embodiments, the second process gas supply part may include: a process gas nozzle disposed in a sidewall of the process chamber; and a lower nozzle line connected to the process gas nozzle to supply the process gas into the process gas nozzle.

In even yet much further embodiments, the process gas nozzle may be provided in plurality along a circumferential direction in the sidewall of the process chamber.

In yet still further embodiments, the process gas nozzle may have a discharge hole with a ring shape in the sidewall of the process chamber.

In yet even further embodiments, the excitation gas supply unit may include: an excitation gas tank storing the excitation gas; an excitation gas nozzle having a discharge hole defined in the upper space; and an excitation gas line connecting the excitation gas tank to the excitation gas nozzle.

In yet even further embodiments, the excitation gas tank may include a first excitation gas tank and a second excitation gas tank which are connected to the excitation gas nozzle in parallel to each other.

In even still much further embodiments, the first excitation gas tank may supply one of helium, argon, and nitrogen into the excitation gas nozzle, and the second excitation gas tank may supply hydrogen into the excitation gas nozzle.

In even yet much further embodiments, the substrate treating apparatuses may further include a cleaning gas supply unit supplying a cleaning gas into the inner space.

In still even much further embodiments, the cleaning gas supply unit may supply the cleaning gas into the lower space.

In still even much further embodiments, the substrate treating apparatuses may further include an exhaust baffle in which the substrate support member is disposed in a center thereof, the exhaust baffle being spaced apart from the bottom of the process chamber.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view of a substrate processing apparatus according to an embodiment of the present invention;

FIG. 2 is a view illustrating a bottom surface of an antenna;

FIG. 3 is a view of a distribution line disposed in a showerhead;

FIG. 4 is a view illustrating a bottom surface of the showerhead;

FIG. 5 is a cross-sectional view taken along line A-A′ of FIG. 3;

FIG. 6 is a view of a substrate on which a pattern is disposed;

FIG. 7 is a cross-sectional view of a rib part according to another embodiment;

FIG. 8 is a cross-sectional view of a rib part according to further another embodiment;

FIG. 9 is a view of a showerhead according to another embodiment;

FIGS. 10 and 11 are views of a showerhead according to further another embodiment;

FIG. 12 is a view of a second process gas supply part according to another embodiment;

FIG. 13 is a view of a second process gas supply part according to further another embodiment;

FIG. 14 is a view of a substrate treating apparatus according to an embodiment of the present invention;

FIG. 15 is a view of an excitation gas supply unit;

FIG. 16 is a plan view of the showerhead;

FIG. 17 is a view of a process gas supply unit;

FIG. 18 is a view of a substrate disposed in the substrate treating apparatus of FIG. 14;

FIG. 19 is a view of a cleaning gas supply unit; and

FIG. 20 is a plan view of an exhaust baffle.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the thicknesses of layers and regions are exaggerated for clarity.

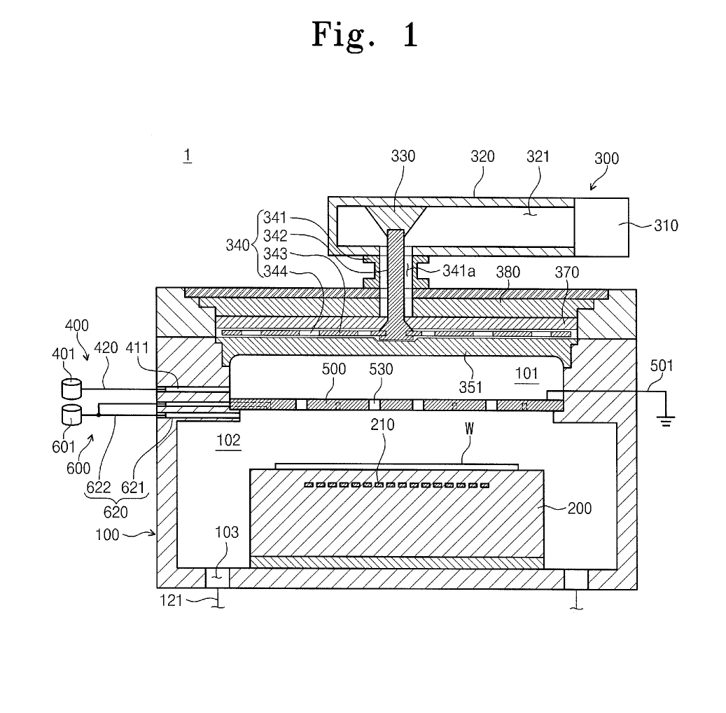

FIG. 1 is a view of a substrate processing apparatus according to an embodiment of the present invention.

Referring to FIG. 1, the substrate treating apparatus 1 includes a process chamber 100, a substrate support member 200, a microwave apply unit 300, an excitation gas supply unit 400, and a process gas supply unit 600. The substrate treating apparatus 1 performs a process of epitaxially growing silicon on a substrate W.

The process chamber 100 is provided with an inner space therein. A showerhead 500 that will be described later is disposed within the process chamber. The showerhead 500 partitions the inner space into an upper space 101 and a lower space 102. An opening (not shown) may be defined in one sidewall of the process chamber 100. The opening may be defined in the lower space 102. The opening may serve as a passage through which the substrate W is loaded into or unloaded from the process chamber 100. The opening is opened or closed by a door (not shown). An exhaust hole 103 is defined in a bottom of the process chamber 100. The exhaust hole 103 is connected to an exhaust line 121. Process byproducts generated during the process and gases staying in the process chamber 100 may be exhausted to the outside through the exhaust line 121.

The substrate support member 200 is disposed within the process chamber 100. The substrate support member 200 is disposed in the lower space 102. The substrate support member 200 supports the substrate W. A heater 210 is disposed in the substrate support member 200. A coil may be provided as heater 210. The coil may have a spiral shape. Alternatively, the coil may be disposed so that rings having different radii have the same center. The heater 210 is electrically connected to an external power source (not shown). The heater 210 generates heat by resisting current applied from the external power source. The generated heat is transferred into the substrate W. The substrate W may be maintained at a predetermined temperature by the heat generated in the heater 210.

The microwave apply unit 300 applies a microwave into the process chamber 100. The microwave apply unit 300 includes a microwave power source 310, a waveguide 320, a coaxial converter 330, an antenna member 340, a dielectric block 351, a dielectric plate 370, and a cooling plate 380.

The microwave power source 310 generates a microwave. For example, the microwave generated in the microwave power source 310 may be a transverse electric mode (TE MODE) having a frequency of about 2.3 GHz to about 2.6 GHz. The waveguide 320 is disposed on a side of the microwave power source 310. The waveguide 320 has a polygonal or circular tube shape in section. The waveguide 320 has an inner surface formed of a conductive material. For example, the inner surface of the waveguide 320 may be formed of gold or silver. The waveguide 320 provides a passage through which the microwave generated in the microwave power source 310 is transmitted.

The coaxial converter 330 is disposed within the waveguide 320. The coaxial converter 330 is disposed on a side opposite to the microwave power source 310. The coaxial converter 330 has one end fixed to the inner surface of the waveguide 320. The coaxial converter 330 may have a small cone shape of which a sectional area of a lower end is less than that of an upper end. The microwave transmitted through an inner space of the waveguide 320 is converted in mode by the coaxial converter 330 and then propagated downward. For example, the microwave may be converted from a transverse electric mode (TE MODE) into a transverse electromagnetic mode (TEM MODE).

The antenna member 340 transmits the microwave that is mode-converted in the coaxial converter 330 downward. The antenna member 340 includes an external conductor 341, an internal conductor 342, and an antenna 343. The external conductor 341 is disposed on a lower portion of the waveguide 320. A space 341a communicating with the inner space of the waveguide 320 is defined downward in the external conductor 341.

The internal conductor 342 is disposed within the external conductor 341. A cylindrical shape may be provided as the internal conductor 342. The internal conductor 342 has a length direction parallel to a vertical direction. An outer circumferential surface of the internal conductor 342 is spaced from the inner surface of the external conductor 341.

An upper end of the internal conductor 342 is inserted into and fixed to a lower end of the coaxial converter 330. The internal conductor 342 extends downward so that a lower end thereof is disposed within the process chamber 100. The lower end of the internal conductor 342 is fixed and coupled to a center of the antenna 343. The internal conductor 342 is vertically disposed on a top surface of the antenna 343.

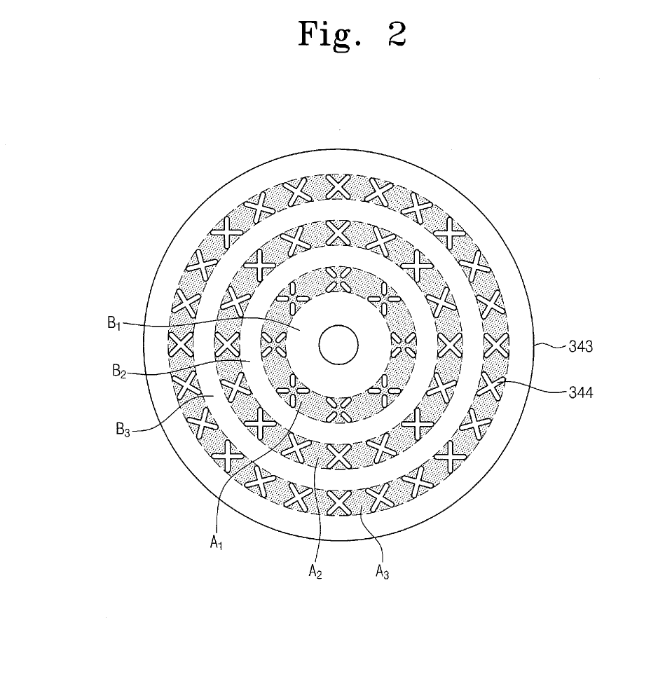

FIG. 2 is a view illustrating a bottom surface of an antenna.

Referring to FIGS. 1 and 2, the antenna 343 has a plate shape. For example, a thin circular plate may be provided as the antenna 343. The antenna 343 is disposed to face the showerhead 500. A plurality of slot holes 344 are defined in the antenna 343. Each of the slot holes 344 may have an “X” shape. The plurality of slot holes 344 are combined with each other and thus disposed in a plurality of ring shapes. Hereinafter, areas of the antenna 343 in which the slot holes 344 are defined are referred to as first areas A1, A2, and A3, and areas of the antenna 343 in which the slot holes 344 are not defined are referred to as second areas B1, B2, and B3. Each of the first areas A1, A2, and A3 and the second areas B1, B2, and B3 has a ring shape. The first areas A1, A2, and A3 are provided in plurality and have radii different from each other. The first areas A1, A2, and A3 may have the same center and be disposed spaced apart from each other in a radius direction of the antenna 343. The second areas B1, B2, and B3 are provided in plurality and have radii different from each other. The second areas B 1, B2, and B3 may have the same center and be disposed spaced apart from each other in a radius direction of the antenna 343. The first areas A1, A2, and A3 are disposed between the second areas B1, B2, and B3 adjacent to each other, respectively. Alternatively, each of the slot holes 344 may have various shapes such as a “−” shape or a “+” shape.

The dielectric plate 370 is disposed on the antenna 343. The dielectric plate 370 may be formed of a dielectric such as alumina or quartz. The microwave vertically propagated from the microwave antenna 343 may be propagated in a radius direction of the dielectric plate 370. The microwave propagated into dielectric plate 370 is pressed in wavelength and then resonated. The resonated microwave is transmitted into the slot holes 344 of the antenna 343. The microwave passing through the antenna 343 may be converted into a plane wave in the TEM mode.

The cooling plate 380 is disposed on the dielectric plate 370. The cooling plate cools the dielectric plate 370. The cooling plate 380 may be formed of an aluminum material. In the cooling plate 380, a cooling fluid may flow into a cooling passage (not shown) defined in the cooling plate 380 to cool the dielectric plate 370. The cooling method may include a water cooling method or an air cooling method.

The dielectric block 351 is disposed under the antenna 343. The dielectric block 351 may have a top surface spaced a predetermined distance from a bottom surface of the antenna 343. Alternatively, the dielectric block 351 may have a top surface contacting the bottom surface of the antenna 343. The dielectric block 351 may be formed of a dielectric such as alumina or quartz. The microwave passing through the slot holes 344 of the antenna 343 may be emitted into the upper space 101 via the dielectric block 351. The microwave has a frequency of gigahertz (GHz). Thus, since the microwave has low transmittance, the microwave does not reach the lower space 102.

The excitation gas supply unit 400 includes an excitation gas tank 401 and an excitation gas nozzle 411. The excitation gas supply unit 400 supplies an excitation gas into the upper space 101.

The excitation gas tank 401 stores the excitation gas. The excitation gas may include hydrogen, helium, argon, or nitrogen. The excitation gas nozzle 411 has a discharge hole defined in the upper space 101. The excitation gas nozzle 411 connects the excitation gas tank 401 to an excitation gas line 420. A valve (not shown) may be provided in the excitation gas line 420. The valve may open or close the excitation gas line 420 and adjusts a flow rate of the excitation gas. The excitation gas is sprayed into the upper space 101 and then is excited in a plasma state by the microwave.

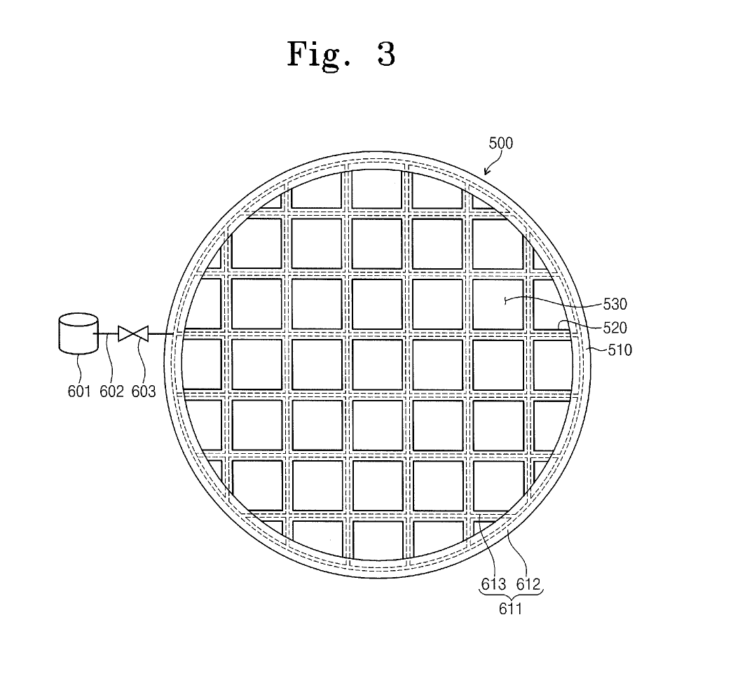

FIG. 3 is a view of a distribution line disposed in the showerhead.

Referring to FIGS. 1 and 3, the showerhead 500 is disposed to face the substrate support member 200. The inner space is partitioned into the upper space 101 and the lower space 102 by the showerhead 500. The showerhead 500 is grounded by a lead wire 501. A fixed part 510 of the showerhead 500 is fixed to a sidewall of the process chamber 100. The fixed part 510 may have a ring shape corresponding to that of the sidewall of the process chamber 100. If the sidewall of the process chamber 100 has a circular shape, the fixed part 510 may have a circular ring shape. Rib parts 520 are disposed inside the fixed part 510. The rib parts 520 may be arranged in a lattice pattern shape. Thus, plasma supply holes are defined between the rib parts 520. The plasma supply holes 530 are uniformly defined inside the fixed part 510. The plasma excited in the upper space 101 is uniformly supplied into the lower space 102 through the plasma supply holes 530. The excited plasma includes plus ions, minus ions, and neutral particles. The plus and minus ions may be migrated to the outside of the process chamber 100 through the lead wire 501. Thus, since the introduction of the plus and minus ions into the lower space 102 may be prevented, a plus charged layer or a minus charged layer is not formed on the substrate W. The plasma supplied into the lower space dissociates a process gas supplied from the process gas supply unit 600.

The process gas supply unit 600 includes a first process gas supply part 610 and a second process gas supply part 620.

The first process gas supply part 610 includes a distribution line 611 and a spray hole 614. The first process gas supply part 610 supplies the process gas into the lower space 102 from the showerhead 500. The distribution line 611 is provided as a tube that is disposed within the fixed part 510 and the rib part 520. A first distribution line 612 is provided in the fixed part 510. The distribution line 611 disposed in the fixed part 510 is connected to the process gas tank 601 through a showerhead line 602. The process gas may include a compound including silicon. For example, the process gas may include silane (SiH₄). The process gas stored in the process gas tank 601 is supplied into the distribution line 611 through the showerhead line 602. A valve 603 may be provided in the showerhead line 602. The valve 603 may open or close the showerhead line 602 and adjust a flow rate of the process gas flowing into the showerhead line 602. A second distribution line 613 is disposed in the rib part 520. The second distribution line 613 communicates with the first distribution line 612. Also, the second distribution lines 613 disposed in the rib part 520 may communicate with each other. The process gas supplied through the showerhead line 602 is distributed through the first distribution line 612. The process gas flows into the first distribution line 612 is introduced into the second distribution lines 613. Thus, the process gas may be uniformly supplied into the second distributions 613.

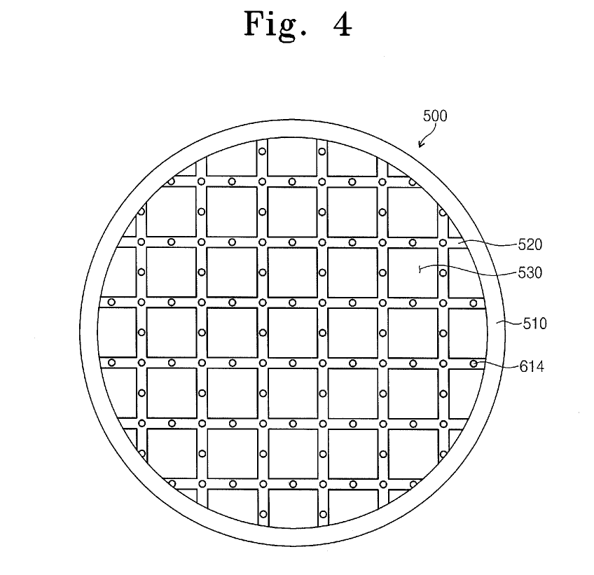

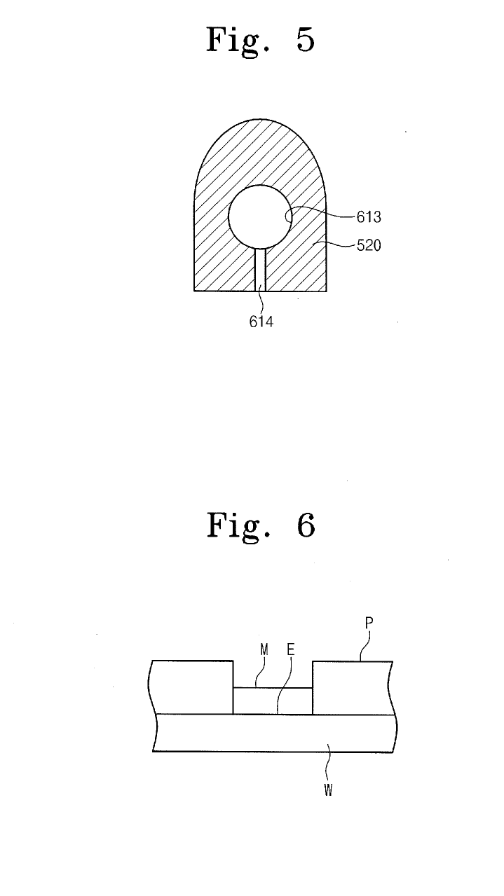

FIG. 4 is a view illustrating a bottom surface of the showerhead, and FIG. 5 is a cross-sectional view taken along line A-A′ of FIG. 3.

Referring to FIGS. 1, and 3 to 5, spray holes 614 are defined in the bottom surface of the showerhead 500. The spray holes 614 are uniformly defined in a bottom surface of the rib part 520. The adjacent holes 614 are spaced a predetermined distance from each other. The spray holes 614 communicate with the second distribution lines 613, respectively. The process gas flowing into the second distribution lines 613 is supplied into the lower space 102 through the spray holes 614. The process gas is dissociated by the plasma supplied through the plasma supply holes 530.

According to an embodiment, the process gas is dissociated by the plasma after the process gas is sprayed into the lower space 102 through the spray holes 614 that are uniformly defined in the showerhead 500. Thus, the process gas may be uniformly supplied onto the substrate after being dissociated.

The second process gas supply part 620 includes a process gas nozzle 621 and a lower nozzle line 622. The second process gas supply part 620 supplies the process gas into the lower space 102. The process gas nozzle 621 is disposed in the sidewall of the process chamber 100. The process gas nozzle 621 may be disposed adjacent to the bottom surface of the showerhead 500. The process gas nozzle 621 is connected to the process gas tank 601 through the lower nozzle line 622. A valve (not shown) may be provided in the lower nozzle line 622. The valve may open or close the lower nozzle line 622 and adjust a flow rate of the process gas flowing into the lower nozzle line 622. The process gas nozzle 621 has a length direction different from a flow direction of the plasma supplied into the plasma supply holes 530. Thus, reactivity between the process gas discharged into the process gas nozzle 621 and the plasma may be improved. The second process gas supply part 620 supplies the process gas into a place adjacent to the sidewall of the process chamber 100. Thus, the process gas may be uniformly supplied into a center of the lower space 102 and a lateral portion of the lower space by the first and second process gas supply parts 610 and 620.

The process gas supplied into the lower space 102 is dissociated by the plasma. For example, silane may be dissociated into hydrogen ions and silicon ions. When the process gas is dissociated by a high frequency microwave, high-density plasma may be generated. The silicon ions are supplied onto the substrate W disposed on the substrate support member 200. Also, the microwave does not reach the lower space 102. Thus, the process gas is not affected by the microwave.

FIG. 6 is a view of a substrate on which a pattern is disposed.

Referring to FIGS. 1 to 6, a process in which silicon is selectively epitaxial-grown on a substrate will be described.

The substrate W is loaded into the process chamber 100 and then disposed on the substrate support member 200. A silicon wafer may be provided as the substrate W. An insulation layer P may be patterned on the substrate W. For example, the insulation layer P may be formed of silicon dioxide. An exposure part E is disposed between the patterns on the substrate W. The silicon is exposed to an upper side through the exposure part E.

A pre-clean process may be performed on the substrate W to remove an oxide layer disposed on a top surface of the substrate W. The excitation gas supply unit 400 supplies the excitation gas into the upper space 101, and the microwave apply unit 300 applies a microwave into the upper space 101. The excitation gas is excited into plasma by the microwave and then supplied into the lower space 102. The oxide layer disposed on the top surface of the substrate W is removed by the plasma generated by the excitation gas.

Also, the substrate W may be loaded into the process chamber 100 in the state where the oxide layer on the substrate W is removed. In this case, the pre-clean process may be omitted.

When the oxide layer is removed, the silicon is selectively epitaxial-grown on the substrate W. The excitation gas supply unit 400 supplies the excitation gas into the upper space 101, and the microwave apply unit 300 applies the microwave into the upper space 101. The excitation gas is supplied into the lower space 102 after the excitation gas is excited into the plasma. A first excitation gas excited into the microwave may generate high-density plasma. The process gas supply unit 600 supplies the process gas into the lower space 102. The process gas is dissociated into plasma in the lower space 102 to supply the silicon ions onto the substrate W. The silicon ions are attached to the exposure part E to selectively epitaxial-grow the silicon. Since the high-density plasma is supplied into the lower space 102, the supplied process gas may be mostly dissociated. The high-density silicon ions may be supplied onto the substrate W. Thus, a high-density silicon layer is formed on the substrate W. The growth of the silicon may be restrained on a top surface of the insulation layer P. The silicon may be grown on the top surface of the insulation layer P into a polycrystalline structure.

After the silicon is selectively epitaxial-grown for a predetermined time, a selective etching process is performed. The selective etching process may performed by using the same method as the pre-clean process. The plasma generated by the excitation gas etches the top surface of the insulation layer P and a top surface of the exposure E. The polycrystalline silicon formed on the top surface of the insulation layer P may be etched at an etching rate faster than that of the monocrystalline silicon formed on the top surface of the exposure part E. Thus, the plasma may be supplied onto the substrate W for a predetermined time to remove the silicon crystal formed on the top surface of the insulation layer P.

The selectively epitaxial growth and the selective etching may be repeated several times. Thus, the monocrystalline silicon to be formed on the top surface of the exposure part E may be adjusted in thickness.

According to an embodiment of the present invention, only the plasma or the process gas dissociated by the plasma is supplied onto the substrate W. The microwave does not reach the lower space 102, or even thought the microwave reaches the lower space 102, the effect of the microwave may be significantly less. Thus, the plasma or the dissociated process gas that is supplied onto the substrate W may have a low temperature when compared to that of a gas used for a selectively epitaxial process according to a related art. If a temperature required for growing the silicon crystal is low, diffusion of impurities contained in the substrate W may be reduced.

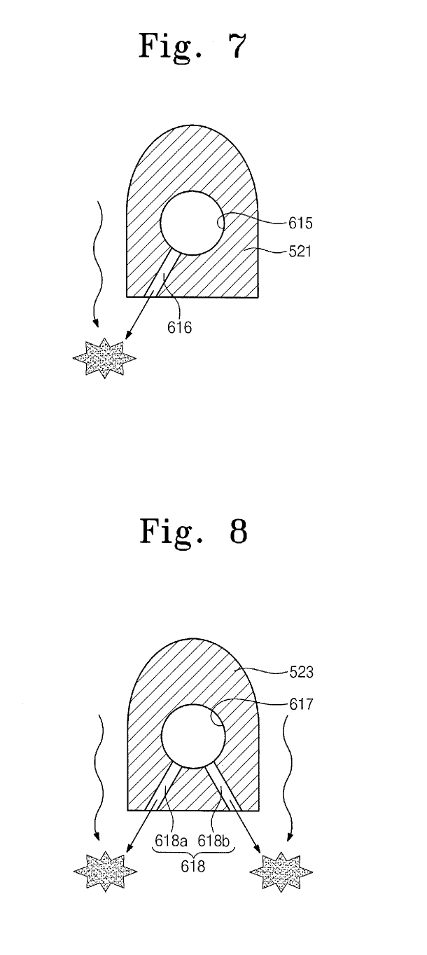

FIG. 7 is a cross-sectional view of a rib part according to another embodiment.

Referring to FIG. 7, each of spray holes 616 may be inclined with respect to a straight line perpendicular to a bottom surface of a showerhead 500. A rib part 521 and a second distribution line 615 may have the same constitute as those of FIGS. 3 and 4. The spray hole 616 inclinedly sprays a flowing process gas. A flow direction of plasma supplied into an upper space may be different from that of the process gas. For example, the plasma may flow in a direction perpendicular to a bottom surface of a process chamber 100 by gravity. Since the plasma and the process gas flow in directions different from each other, the number of collision and a degree of energy transfer may increase.

In another embodiment of the present invention, reactivity between the process gas sprayed through the spray holes 616 and the plasma may increase.

FIG. 8 is a cross-sectional view of a rib part according to further another embodiment.

Referring to FIG. 8, adjacent spray holes 616 may be provided in pair. A rib part 523 and a second distribution line 617 may have the same constitute as those of FIGS. 3 and 4. A first spray hole 618a and a second spray hole 618b may be inclined with respect to a straight line perpendicular to a bottom surface of a showerhead 500. The first and second spray holes 618a and 618b may be inclined in different directions, respectively. Thus, a process gas sprayed from the first spray hole 618a and a process gas sprayed from the second spray hole 618b may flow toward lower portions of plasma supply holes 530 different from each other. Since the process gas has a flow direction different from that of the plasma, reactivity between the process gas and the plasma may increase. Also, a large amount of process gas may be uniformly supplied into the lower portions of the plasma supply holes 530. Thus, highly densed and associated process gas may be supplied onto a substrate.

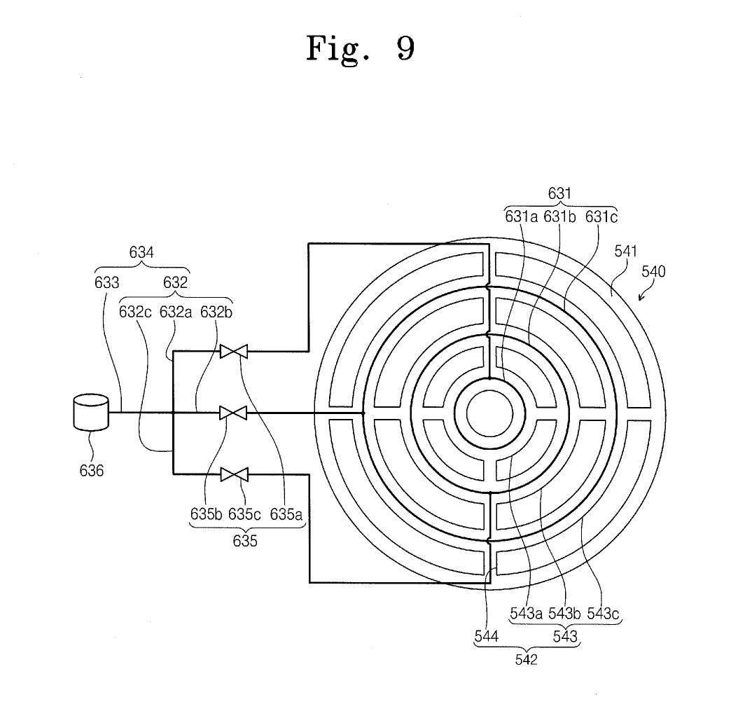

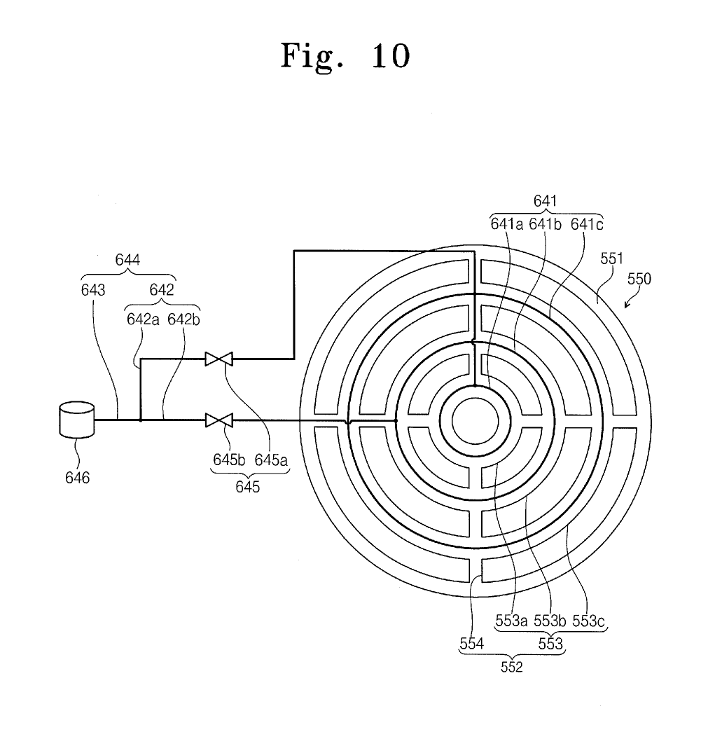

FIG. 9 is a view of a showerhead according to another embodiment.

Referring to FIG. 9, a rib part 542 includes distribution rib parts 543 and connection rib parts 544.

The distribution parts 543 may be provided in a plurality of ring shapes having radii different from each other with respect to a center of a showerhead 540. For example, a second distribution rib part 543b and a third distribution rib part 543c may be successively disposed outside a first distribution rib part 543a having the smallest radius. A distance between the distribution rib parts 543 may be the same. The adjacent distribution rib parts 543 and the third distribution part 543c and a fixed part 541 may be connected to each other through the connection rib parts 544, respectively.

A distribution line 631 is disposed inside each of the distribution parts 543 along a circumferential direction. The distribution lines 631 are not connected to each other, but define separate passages. Each of the distribution lines 631 is connected to a process gas tank 601 through a showerhead line 634. For example, the first distribution line 631a, the second distribution line 631b, and the third distribution line 631c are connected to a first branch line 632a, a second branch line 632b, and a third branch line 632c, respectively. The first to third branch lines 632a to 632c are disposed in parallel to each other. A valve 635 is provided in each of the first to third branch lines 632a to 632c. A first valve 635a, a second valve 635b, and a third valve 635c may open or close the first to third branch lines 632a to 632c and adjust flow amounts of process gas, respectively. The first to third branch lines 632a and 632c may be connected to a main line 633 that is connected to a process gas tank 636. Alternatively, the first to third branch lines 632a to 632c may be directly connected to the process gas tank 601. Spray holes (not shown) connected to the distribution lines 631 are defined in the distribution rib parts 543, respectively.

According to an embodiment of the present invention, an amount of process gas flowing into each of the branch lines may be adjusted. Thus, the amount of process gas existing in a lower space may be adjusted.

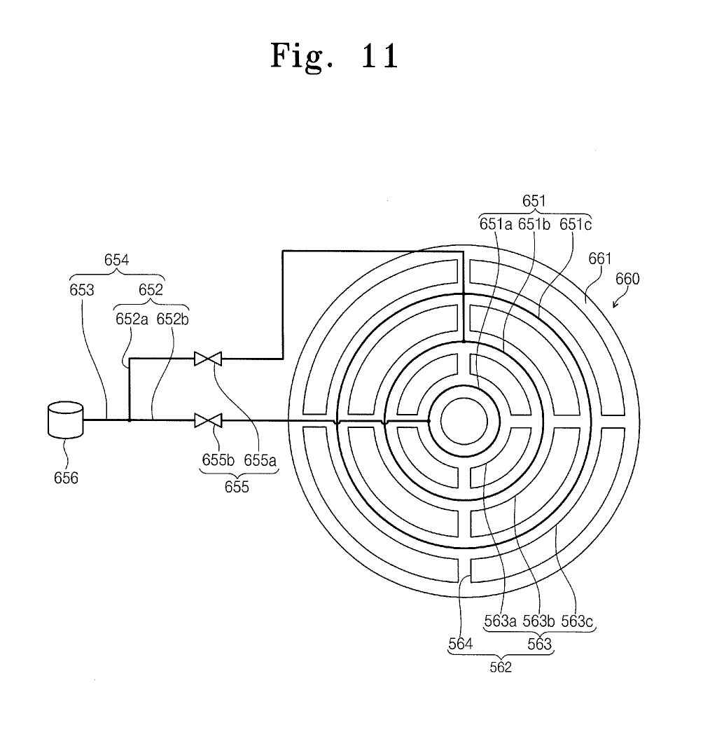

FIGS. 10 and 11 are views of a showerhead according to further another embodiment.

Referring to FIG. 10, a rib part 552 includes distribution rib parts 553 and connection rib parts 554. A first distribution rib part 553a, a second distribution rib part 553b, a third distribution rib part 553c, and the connection rib parts 554 which are provided in a showerhead 550 may have the same constitute as those of the showerhead 540 of FIG. 9. The distribution line 641 is connected to a process gas tank 646 through a showerhead line 644. The distribution lines 641 that are not adjacent to each other may communicate with each other. For example, the first distribution line 641a and the third distribution line 641c may communicate with each other. The first distribution line 641a and the third distribution line 641c are connected to the first branch line 642a. The second distribution line 641b is connected to a second branch line 642b. The first branch line 642a and the second branch line 642b are disposed in parallel to each other. A valve 645 is provided in each of the first and second branch lines 642a and 642b. A first valve 645a and a second valve 645b may open or close the first and second branch lines 642a to 642b and adjust flow amounts of process gas, respectively. The first and second branch lines 642a and 642b may be connected to a main line 643 that is connected to a process gas tank 646.

Referring to FIG. 11, a rib part 562 includes distribution rib parts 563 and connection rib parts 564. A first distribution rib part 563a, a second distribution rib part 563b, a third distribution rib part 563c, and the connection rib parts 564 which are provided in a showerhead 560 may have the same constitute as those of the showerhead 540 of FIG. 9. The distribution lines 651 that are not adjacent to each other may communicate with each other. The distribution line 651 is connected to a process gas tank 654 through a showerhead line 656. For example, the second distribution line 651b and the third distribution line 651c may communicate with each other. A first distribution line 651a is connected to a first branch line 652a. The first distribution line 652a and the third distribution line 651c are connected to the second branch line 652b. A valve 655 is provided in each of the first and second branch lines 652a and 642b. A first valve 655a and a second valve 655b may open or close the first and second branch lines 652a to 652b and adjust flow amounts of process gas, respectively. The first and second branch lines 652a and 652b may be connected to a main line 652 that is connected to a process gas tank 653.

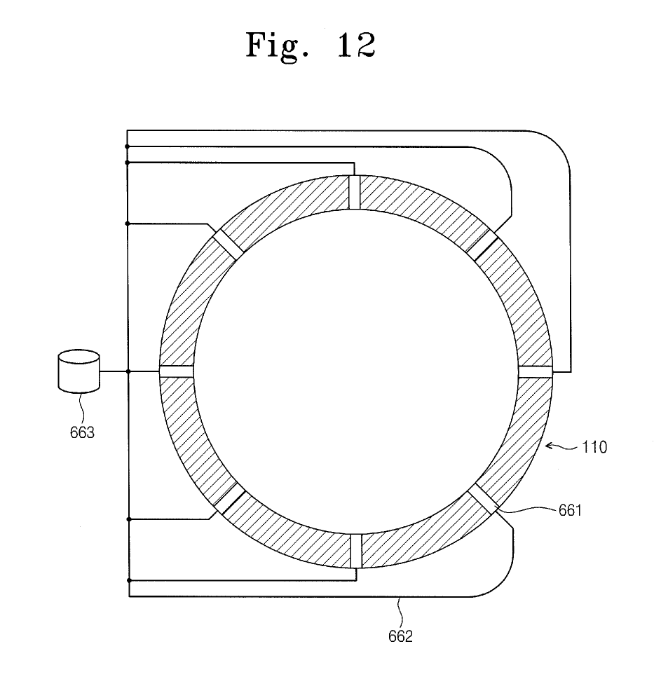

FIG. 12 is a view of a second process gas supply part according to another embodiment.

Referring to FIG. 12, a process gas nozzle 661 may be provided in plurality. The plurality of process gas nozzles 661 are arranged along a circumferential direction on a sidewall of a process chamber 110. The process gas nozzles 661 may be arranged with a predetermined distance. Each of the process gas nozzles 661 is connected to a process gas tank 663 through a lower nozzle line 662.

According to an embodiment of the present invention, a process gas may be uniformly supplied into a lower space adjacent to the sidewall of the process chamber 110.

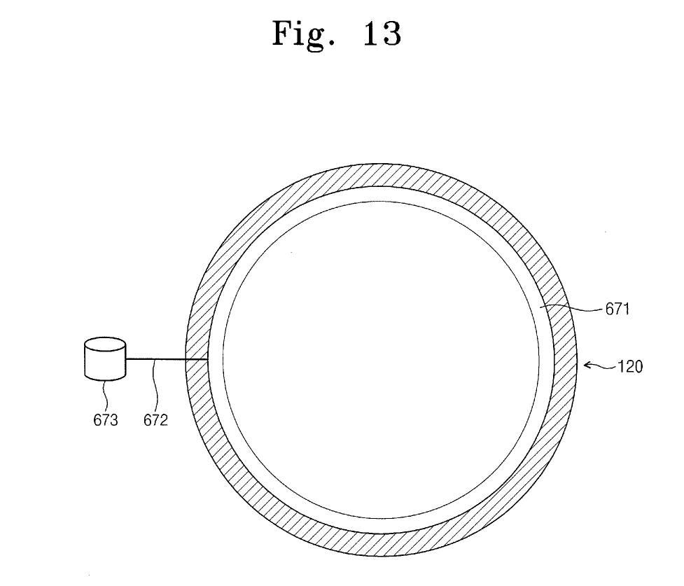

FIG. 13 is a view of a second process gas supply part according to further another embodiment.

Referring to FIG. 13, a process gas nozzle 671 may have a ring shape. Thus, a discharge hole of the process gas nozzle 671 may be defined in a ring shape in a sidewall of a process chamber 120.

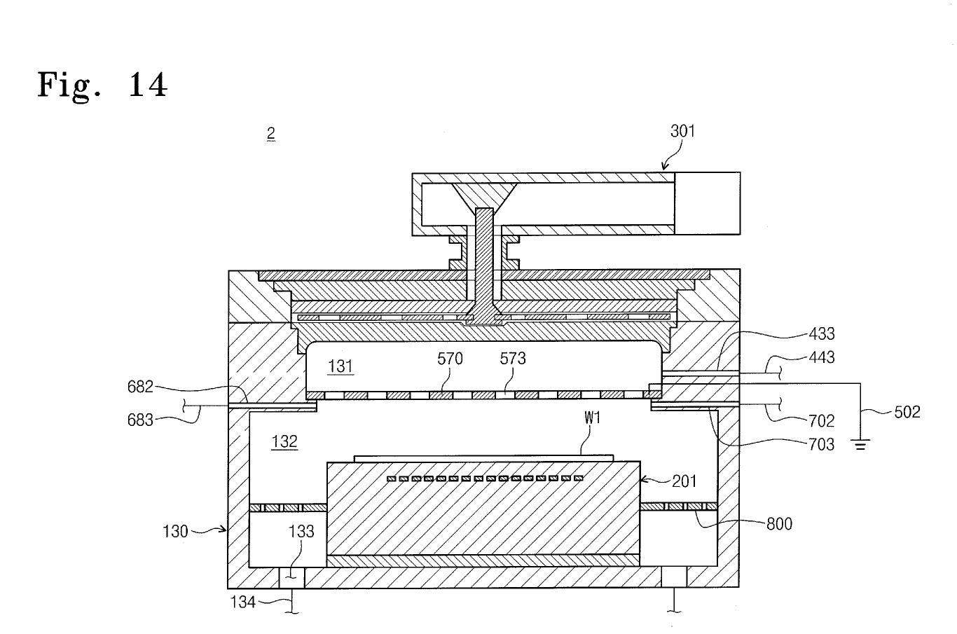

FIG. 14 is a view of a substrate treating apparatus according to an embodiment of the present invention.

Referring to FIG. 14, a substrate treating apparatus 2 includes a process chamber 130, a substrate support member 201, a microwave apply unit 301, an excitation gas supply unit 430, a process gas supply unit 680, and a cleaning gas supply unit 700. The substrate treating apparatus 2 performs a process of epitaxially growing silicon on a substrate W1.

The process chamber, the substrate support member, the microwave apply unit, an exhaust hole defined in the process chamber, and an exhaust line connected to the exhaust hole are the same as those of the substrate treating apparatus 1 of FIG. 1, and thus, descriptions with respect to their duplicated parts will be omitted.

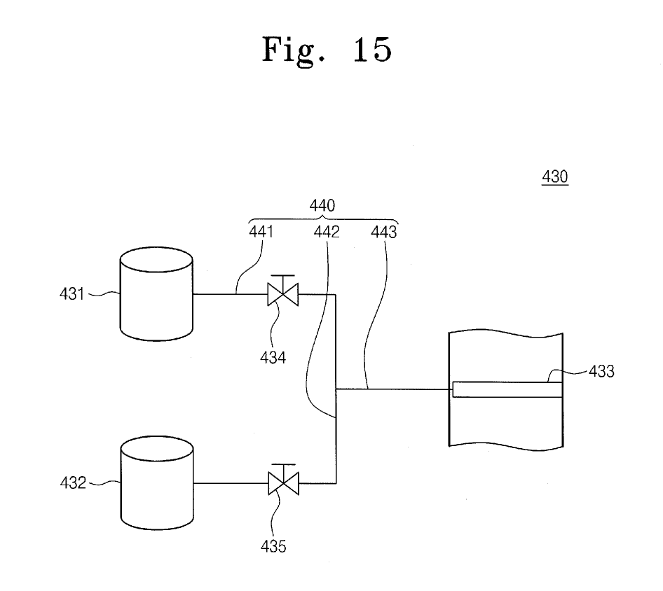

FIG. 15 is a view of an excitation gas supply unit.

Referring to FIGS. 14 and 15, the excitation gas supply unit 430 includes excitation gas tanks 431 and 432 and an excitation gas nozzle 433. The excitation gas supply unit 430 supplies an excitation gas into an upper space 131.

The excitation gas tanks 431 and 432 store the excitation gas. The excitation gas tanks 431 and 432 may be provided in two. The first and second excitation gas tanks 431 and 432 store first and second excitation gases, respectively. The first excitation gas stored in the first excitation gas tank 431 may include one of hydrogen, helium, argon, and nitrogen. The second excitation gas stored in the second excitation gas tank 432 may be hydrogen or chlorine.

The excitation gas nozzle 433 has a discharge hole defined in the upper space 131. The excitation gas nozzle 433 connects the excitation gas tanks 431 and 432 to each other through an excitation gas line 440. The first and second excitation gas tanks 431 and 432 are connected to first and second branch lines 441 and 442 in parallel to each other, respectively. The first and second branch lines 441 and 442 are connected to one end of a main line 443. The main line 443 has the other end connected to the excitation gas nozzle 433. Valves 434 and 435 may be provided the first and second branch lines 441 and 442, respectively. The first valve 434 may open or close the first branch line 441 and adjust a flow rate of the first excitation gas. The second valve 435 may open or close the second branch line 442 and adjust a flow rate of the second excitation gas. The first or second excitation gas is sprayed into the upper space 131 and then is excited in a plasma state by a microwave.

The excitation gas supply unit 430 may also be provided in the substrate treating apparatus 1 of FIG. 1.

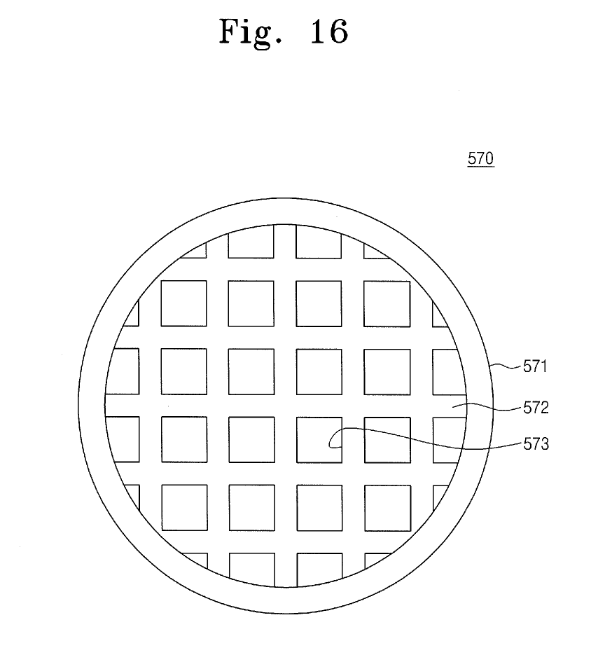

FIG. 16 is a plan view of the showerhead.

Referring to FIGS. 14 and 16, a showerhead 570 is disposed to face the substrate support member 201. An inner space is partitioned into the upper space 131 and a lower space 132 by the showerhead 570. The showerhead 570 is grounded by a lead wire 502. The distribution line and the spray hole which are provided in the showerhead of FIG. 3 may be omitted in the showerhead 570. Since a fixed part, a rib part, a supply hole defined in the showerhead, and functions of the showerhead are the same as those of the showerhead of FIG. 3, their duplicated descriptions will be omitted.

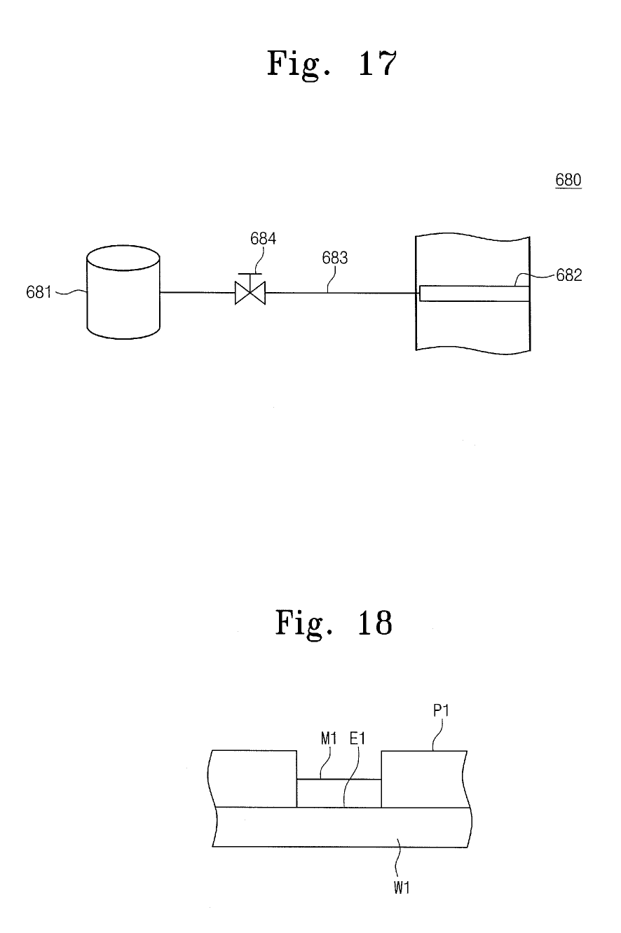

FIG. 17 is a view of the process gas supply unit.

Referring to FIG. 17, the process gas supply unit 680 includes a process gas tank 681 and a process gas nozzle 682. The process gas supply unit 680 supplies a process gas into the lower space 132.

The process gas tank 681 stores the process gas. A compound including silicon may be provided as the process gas. For example, the process gas may include silane (SiH₄). The process gas nozzle 682 has a discharge hole defined in the lower space 132. The process gas nozzle 682 is connected to the process gas tank 681 through a process gas line 683. A valve 604 may be provided in the process gas line 683. The valve 604 may open or close the process gas line 683 and adjust a flow rate of the process gas flowing into the process gas line 683. The process gas supplied into the lower space 132 is dissociated by plasma. For example, silane may be dissociated into hydrogen ions and silicon ions. When the process gas is dissociated by a high frequency microwave, high-density plasma may be generated. The silicon ions are supplied onto the substrate W1 disposed on the substrate support member 201. Also, the microwave does not reach the lower space 132. Thus, the process gas is not affected by the microwave.

FIG. 18 is a view of a substrate disposed in the substrate treating apparatus of FIG. 14.

Referring to FIGS. 14 to 18, a process in which the silicon is selectively epitaxial-grown on the substrate W1 will be described.

The substrate W1 is loaded into the process chamber 130 and then disposed on the substrate support member 201. Since an insulation layer P1 and an exposure part E1 which are disposed on the substrate W1 are the same as those of the substrate W of FIG. 6, their duplicated descriptions will be omitted.

A pre-clean process may be performed on the substrate W1 to remove an oxide layer disposed on a top surface of the substrate W1. The excitation gas supply unit 430 supplies the second excitation gas into the upper space 131, and the microwave apply unit 301 applies a microwave into the upper space 131. The second excitation gas is excited into the plasma by the microwave and then supplied into the lower space 132. The oxide layer disposed on the top surface of the substrate W1 is removed by the plasma generated by the excitation gas.

Also, the substrate W1 may be loaded into the process chamber 130 in the state where the oxide layer is removed. In this case, the pre-clean process may be omitted.

When the oxide layer is removed, the silicon is selectively epitaxial-grown on the substrate W1. The excitation gas supply unit 430 supplies the first excitation gas into the upper space 131, and the microwave apply unit 301 applies a microwave into the upper space 131. The first excitation gas is supplied into the lower space 132 after the excitation gas is excited into the plasma. The first excitation gas excited into the microwave may generate high-density plasma. The process gas supply unit 680 supplies the process gas into the lower space 132. The process gas is dissociated into the plasma in the lower space 132 to supply the silicon ions onto the substrate W1. The silicon ions are attached to the exposure part E1 to selectively epitaxial-grow the silicon. Since the high-density plasma is supplied into the lower space 132, the supplied process gas may be mostly dissociated. The high-density silicon ions may be supplied onto the substrate W1. Thus, a high-density silicon layer is formed on the substrate W1. The growth of the silicon may be restrained on a top surface of the insulation layer P1. The silicon may be grown on the top surface of the insulation layer P1 into a polycrystalline structure.

After the silicon is selectively epitaxial-grown for a predetermined time, a selective etching process is performed. The selective etching process may performed by using the same method as the pre-clean process. The plasma generated by the second excitation gas etches the top surface of the insulation layer P1 and a top surface of the exposure E1. The polycrystalline silicon formed on the top surface of the insulation layer P1 may be etched at an etching rate faster than that of a monocrystalline silicon layer M1 formed on the top surface of the exposure part E1. Thus, the plasma may be supplied onto the substrate W1 for a predetermined time to remove the silicon crystal formed on the top surface of the insulation layer P1.

The selectively epitaxial growth and the selective etching may be repeated several times. Thus, the monocrystalline silicon layer M1 to be formed on the top surface of the exposure part E1 may be adjusted in thickness.

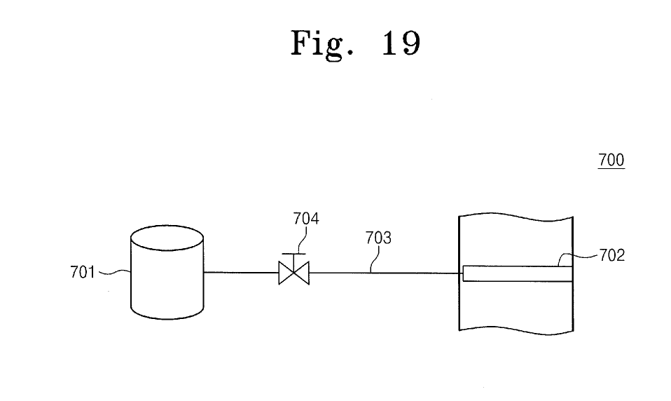

FIG. 19 is a view of the cleaning gas supply unit.

Referring to FIG. 19, the cleaning gas supply unit 700 includes a cleaning gas tank 701 and a cleaning gas nozzle 702.

The cleaning gas tank 701 stores a cleaning gas. Nitrogen fluoride (NF₃) may be provided as the cleaning gas. The cleaning gas nozzle 702 is disposed in the lower space 132. The cleaning gas nozzle 702 is connected to the cleaning gas tank 701 through a cleaning gas line 703. A valve 704 is provided in the cleaning gas line 703. The valve 704 may open or close the cleaning gas line 703 and adjust a flow rate of the cleaning gas flowing into the cleaning gas line 703. The cleaning gas supply unit 700 supplies the cleaning gas into the lower space 132. When the selectively epitaxial growth of the silicon on the substrate W1 is finished, the substrate W1 is unloaded from the process chamber 130. Then, a cleaning process may be performed before a new substrate is loaded into the process chamber 130. The excitation gas supply unit 430 supplies the first or second excitation gas into the upper space 131, and the microwave apply unit 301 applies a microwave into the upper space 131. The first or second excitation gas is supplied into the upper space 131 after the first or second excitation gas is excited into the plasma the microwave. The cleaning gas supply unit 700 supplies the cleaning gas into the lower space 132. The cleaning gas is decomposed to generate fluorine radicals. The fluorine radicals clean an inner wall of the process chamber 130.

Also, the cleaning gas supply unit 700 may provided in the substrate treating apparatus 1 of FIG. 1

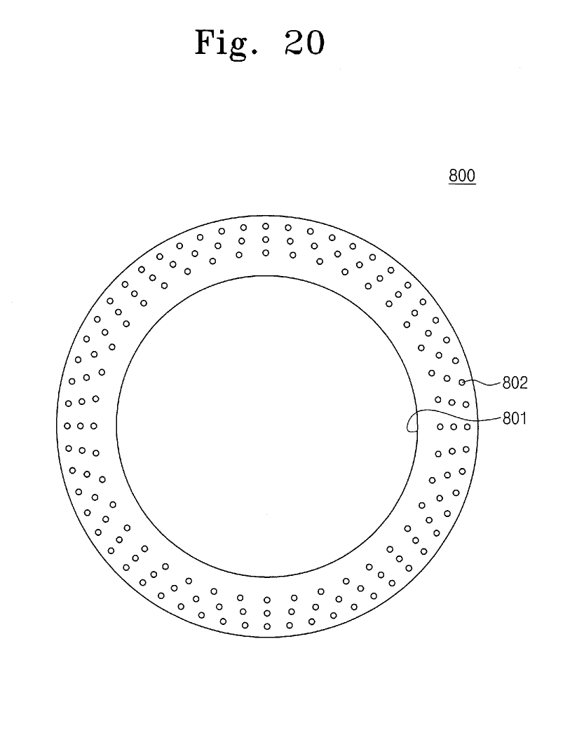

FIG. 20 is a plan view of an exhaust baffle.

Referring to FIGS. 14 and 20, an exhaust baffle 800 is disposed spaced a predetermined distance upward from the bottom of the process chamber 130. The exhaust baffle 800 covers a space between a side surface of the substrate support member 201 and a sidewall of the process chamber 130. A hole 801 corresponding to the substrate support member 201 is defined in a center of the exhaust baffle 800. The substrate support member 201 is disposed in the hole 801. Suction holes 802 are defined outside the hole 801 in the exhaust baffle 800. The suction holes 802 may be uniformly defined along a circumferential direction to form a ring shape. The suction holes 802 may be disposed so that several rings having radii different from each other are formed. While the pre-clean process, the selectively epitaxial process, the selective etching process, or the cleaning process is performed, gases and process byproducts within the process chamber 130 are exhausted through the suction holes 802 and the exhaust hole. The gases and byproducts within the inner space may uniformly flow by the suction holes 802.

The exhaust baffle may also be provided in the substrate treating apparatus 1 of FIG. 1.

According to an embodiment of the present invention, the plasma may be generated by using the microwave.

Also, according to an embodiment of the present invention, the high-density silicon layer may be formed on the substrate.

Also, according to an embodiment of the present invention, the silicon layer may be formed on the substrate at a low temperature.

Also, according to an embodiment of the present invention, the diffusion of the impurities may be prevented.

Also, according to an embodiment of the present invention, the distribution of the layer to be formed on the substrate may be adjusted.

The foregoing detailed descriptions may be merely an example of the prevent invention. Having now described exemplary embodiments, those skilled in the art will appreciate that modifications may be made to them without departing from the spirit of the concepts that are embodied in them. Further, it is not intended that the scope of this application be limited to these specific embodiments or to their specific features or benefits. Rather, it is intended that the scope of this application be limited solely to the claims which now follow and to their equivalents.

What is claimed is:

1. A substrate treating apparatus comprising:
a process chamber providing an inner space in which a substrate is treated;
a substrate support member disposed within the process chamber to support the substrate;
a showerhead disposed to face the substrate support member and partitioning the inner space into an upper space and a lower space, the showerhead having a plasma supply hole through which the upper space and the lower space communicate with each other;
an excitation gas supply unit supplying an excitation gas into the upper space;
a process gas supply unit supplying a process gas into the lower space; and
a microwave apply unit applying a microwave into the upper space.

2. The substrate treating apparatus of claim 1, wherein the process gas supply unit comprises:
a first process gas supply part supplying the process gas into the lower space from the showerhead; and
a second process gas supply part supplying the process gas into the lower space from an inner wall of the process chamber.

3. The substrate treating apparatus of claim 2, wherein the first process gas supply part comprises:
a distribution line through which the excitation gas flows, the distribution line being disposed within the showerhead; and
spray holes defined in a bottom surface of the showerhead to communicate with the distribution line, the spry holes spraying the process gas into the lower space.

4. The substrate treating apparatus of claim 3, wherein each of the spray holes is inclined with respect to a straight line perpendicular to the bottom surface of the showerhead.

5. The substrate treating apparatus of claim 3, wherein the spray holes comprise:
a first spray hole inclined with respect to a straight line perpendicular to the bottom surface of the showerhead; and
a second spray hole inclined with respect to the straight line in a direction different from that of the first spray hole.

6. The substrate treating apparatus of claim 3, wherein the showerhead comprises:
a fixed part fixed to the process chamber; and
rib parts extending inward from the fixed part,
wherein the plasma supply hole is defined between the rib parts or between the rib parts and the fixed part.

7. The substrate treating apparatus of claim 6, wherein the distribution line is disposed inside the rib parts, and
the spray holes are defined in the rib parts, respectively.

8. The substrate treating apparatus of claim 6, wherein the distribution line is disposed inside the fixed part and the rib parts, and
the spray holes are defined in the rib parts, respectively.

9. The substrate treating apparatus of claim 6, wherein the rib parts comprise:
a plurality of distribution rib parts having radii different from each other with respect to a center of the showerhead; and
a connection rib part disposed between the distribution rib parts or between the distribution rib parts and the fixed part.

10. The substrate treating apparatus of claim 9, further comprising:
a process gas tank supplying the process gas; and
a showerhead line connecting the process gas tank to the distribution line.

11. The substrate treating apparatus of claim 10, wherein the distribution line is provided in plurality in each of the distribution ribs, and the plurality of distribution lines respectively have separate passages, and
the showerhead line is branched and connected to each of the distribution lines having the separate passages.

12. The substrate treating apparatus of claim 10, wherein the distribution rib parts comprise:
a first distribution rib part, a second distribution rib part, and a third distribution rib part which are successively disposed in a radius direction of the showerhead, and
the distribution line comprises a first distribution line, a second distribution line, and a third distribution line which are respectively disposed in the first distribution rib part, the second distribution rib part, and the third distribution rib part.

13. The substrate treating apparatus of claim 12, wherein the first distribution line and the second distribution line communicate with each other, and
the third distribution line has a passage different from those of the first and second distribution lines.

14. The substrate treating apparatus of claim 12, wherein the first distribution line and the third distribution line communicate with each other, and
the second distribution line has a passage different from those of the first and third distribution lines.

15. The substrate treating apparatus of claim 2, wherein the second process gas supply part comprises:
a process gas nozzle disposed in a sidewall of the process chamber; and
a lower nozzle line connected to the process gas nozzle to supply the process gas into the process gas nozzle.

16. The substrate treating apparatus of claim 15, wherein the process gas nozzle is provided in plurality along a circumferential direction in the sidewall of the process chamber.

17. The substrate treating apparatus of claim 15, wherein the process gas nozzle has a discharge hole with a ring shape in the sidewall of the process chamber.

18. The substrate treating apparatus of claim 1, wherein the excitation gas supply unit comprises:
an excitation gas tank storing the excitation gas;
an excitation gas nozzle having a discharge hole defined in the upper space; and
an excitation gas line connecting the excitation gas tank to the excitation gas nozzle.

19. The substrate treating apparatus of claim 18, wherein the excitation gas tank comprises a first excitation gas tank and a second excitation gas tank which are connected to the excitation gas nozzle in parallel to each other.

20. The substrate treating apparatus of claim 19, wherein the first excitation gas tank supplies one of helium, argon, and nitrogen into the excitation gas nozzle, and
the second excitation gas tank supplies hydrogen into the excitation gas nozzle.

21. The substrate treating apparatus of claim 1, further comprising a cleaning gas supply unit supplying a cleaning gas into the inner space.

22. The substrate treating apparatus of claim 21, wherein the cleaning gas supply unit supplies the cleaning gas into the lower space.

23. The substrate treating apparatus of claim 1, further comprising an exhaust baffle in which the substrate support member is disposed in a center thereof, the exhaust baffle being spaced apart from the bottom of the process chamber.
